(19) United States
(12) Patent Application Publication
(10) Pub. No.: US 2010/0184250 A1
(43) Pub. Date: Jul. 22, 2010

(54) SELF-ALIGNED SELECTIVE EMITTER FORMED BY COUNTERDOPING

(76) Inventors: Julian Blake, Gloucester, MA (US); Russell Low, Rowley, MA (US)

Correspondence Address: Nields, Lemack & Frame, LLC, 176 E. MAIN STREET, SUITE 5, WESTBOROUGH, MA, 01581, US

(21) Appl. No.: 12/688,958

(22) Filed: Jan. 18, 2010

Related U.S. Application Data
(60) Provisional application No. 61/146,542, filed on Jan. 22, 2009.

(51) Int. Cl. H01L 31/18; H01L 31/0224

(52) U.S. Cl. 438/72; 438/98; 257/E31.119; 257/E31.127; 257/E31.124

(57) ABSTRACT

An improved method of doping substrates, such as a solar cell, is disclosed. Conductors, such as metal lines, are often deposited on the surface of a substrate. In some embodiments, the conductivity of the substrate beneath the conductors is different than the conductivity of other regions of the substrate. Therefore, the conductors can serve as the mask for a subsequent blanket doping, which changes the conductivity of the surface of the substrate, except beneath the conductors. In some embodiments, an initial blanket doping is performed prior to the deposition of the conductors to create an initial uniformly doped region.

This application claims priority of U.S. Provisional Patent Application Ser. No. 61/146,542, filed Jan. 22, 2009, the disclosure of which is incorporated herein by reference in its entirety.

### FIELD

This invention relates to doping solar cells, and, more particularly, to counterdoping a solar cell.

### BACKGROUND

Ion implantation is a standard technique for introducing conductivity-altering impurities into substrates. A desired impurity material is ionized in an ion source, the ions are accelerated to form an ion beam of prescribed energy, and the ion beam is directed at the surface of the substrate. The energetic ions in the beam penetrate into the bulk of the substrate material and are embedded into the crystalline lattice of the substrate material to form a region of desired conductivity.

Solar cells are only one example of a device that uses silicon substrates, and these solar cells are becoming more important globally. Any reduced cost to the manufacture or production of high-performance solar cells or any efficiency improvement to high-performance solar cells would have a positive impact on the implementation of solar cells worldwide. This will enable the wider availability of this clean energy technology.

In fabricating a solar cell, two factors must be considered. The first factor is series resistance (Rₛ), or the total resistance of the solar cell material. Series resistance limits the fill factor, or the ratio of the maximum power point divided by the product of the open circuit voltage (V_{oc}) and the short circuit current (I_{sc}). As series resistance increases, the voltage drop between the junction voltage and the terminal voltage becomes greater for the same flow of current. This results in a significant decrease in the terminal voltage V and a slight reduction in I_{sc}. Very high values of Rₛ also produce a significant reduction in I_{sc}. In such regimes, the series resistance dominates and the behavior of the solar cell resembles that of a resistor. Thus, if V_{oc} and/or I_{sc} decrease, then the cell efficiency decreases as well. This decrease may be a linear function in one instance.

The second factor is photon conversion efficiency, which limits short circuit current. If the front surface of a solar cell is doped at a high level, series resistance will be reduced but recombination loss of the charge carriers increases. This recombination occurs due to interstitial dopants that are not incorporated into the crystal lattice. These dopant sites become recombination centers. This phenomenon is called Shockley-Read-Hall Recombination. A solution that reduces recombination loss is to elevate doping levels only under the front surface contacts of the solar cell. This technique is known as a selective emitter.

One method in forming a selective emitter in a solar cell is to perform a high-dose implant selectively in a region where the metal contacts will eventually be formed. This requires either an expensive photolithography step or the use of a shadow or stencil mask to perform a selective or patterned implant. If a mask is used, it must be carefully aligned to the eventual contact areas. This requires an accuracy of approximately 10-20 μm for current solar cell designs. Accordingly, there is a need in the art for an improved method of doping solar cells using counterdoping.

### SUMMARY

An improved method of doping substrates, and particularly solar cells, is disclosed. Conductors, such as metal lines, are often deposited on the surface of a substrate. In some embodiments, it is desirable that the conductivity of the substrate beneath the conductors is different than the conductivity of other regions of the substrate. Therefore, the conductors can serve as the mask for a subsequent blanket doping, which changes the conductivity of the surface of the substrate, except beneath the conductors. In some embodiments, an initial blanket doping is performed prior to the deposition of the conductors to create an initial uniformly doped region.

### BRIEF DESCRIPTION OF THE DRAWINGS

For a better understanding of the present disclosure, reference is made to the accompanying drawings, which are incorporated herein by reference and in which:

FIG. 1 is cross-sectional view of an embodiment of an exemplary front surface solar cell;

FIG. 2 is a perspective view of an embodiment of counterdoping in a solar cell;

FIG. 3 is a first embodiment of a solar cell fabrication process flow;

FIG. 4 is a second embodiment of a solar cell fabrication process flow;

FIG. 5 is a third embodiment of a solar cell fabrication process flow;

FIG. 6 is a fourth embodiment of a solar cell fabrication process flow;

FIG. 7 is a fifth embodiment of a solar cell fabrication process flow;

FIG. 8 is a sixth embodiment of a solar cell fabrication process flow;

FIGS. 9A-D show the substrate as it undergoes the solar cell fabrication process flow of FIG. 7; and

FIGS. 10A-C show a substrate as it undergoes another solar cell fabrication process flow.

### DETAILED DESCRIPTION

The embodiments of the process described herein may be performed by, for example, a beam-line ion implanter or a plasma doping ion implanter. Such a plasma doping ion implanter may use RF or other plasma generation sources. Other plasma processing equipment or equipment that generates ions also may be used. Thermal or furnace diffusion, pastes on the surface of the solar cell substrate that are heated, epitaxial growth, or laser doping also may be used to perform certain embodiments of the process described herein. Furthermore, while a silicon solar cell is specifically disclosed, other solar cell substrate materials also may benefit from embodiments of the process described herein.

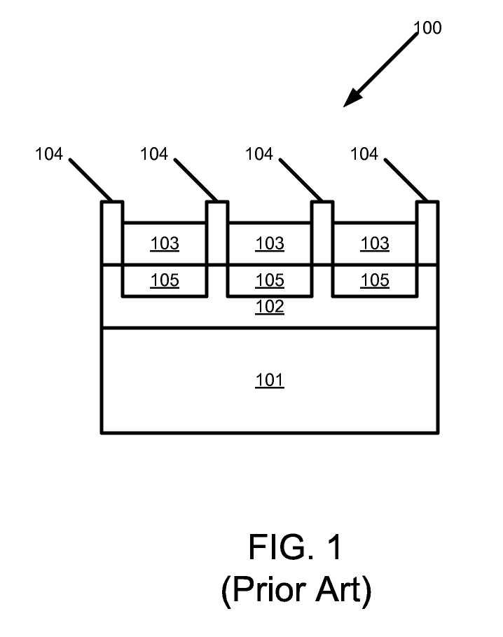

FIG. 1 is cross-sectional view of an embodiment of an exemplary front surface solar cell. Other embodiments or designs are possible and the embodiments of the process described herein are not solely limited to the solar cell 100 illustrated in FIG. 1. The solar cell 100 includes a base region 101 and an emitter 102. The base 101 and emitter 102 are oppositely doped such that one is n-type and the other is p-type. Above the emitter 102 is an anti-reflective coating 103. This anti-reflective coating 103 may be SiN. In one particular embodiment, an oxide layer (not illustrated) is disposed between the anti-reflective coating 103 and the emitter 102. Conductors, such as metal lines, 104 are located above the emitter 102 within the anti-reflective coating 103. A lightly doped region 105 is located within the emitter 102 between the conductors 104.

A phenomenon called “counterdoping” or “compensation” is known in the semiconductor industry. Specifically if both p-type and n-type dopants are combined in the same region of silicon, the resulting structure behaves electrically as though it had been doped with the difference in the p-type and n-type concentrations. For example if p-type dopant of a concentration of 5E19 cm⁻³ is combined with n-type dopant of a concentration of 4E19 cm⁻³, the silicon behaves as though it had p-type dopant of a concentration of 1E19 cm⁻³. Thus counterdoping or compensation can be used to reduce the effective dose of a dopant.

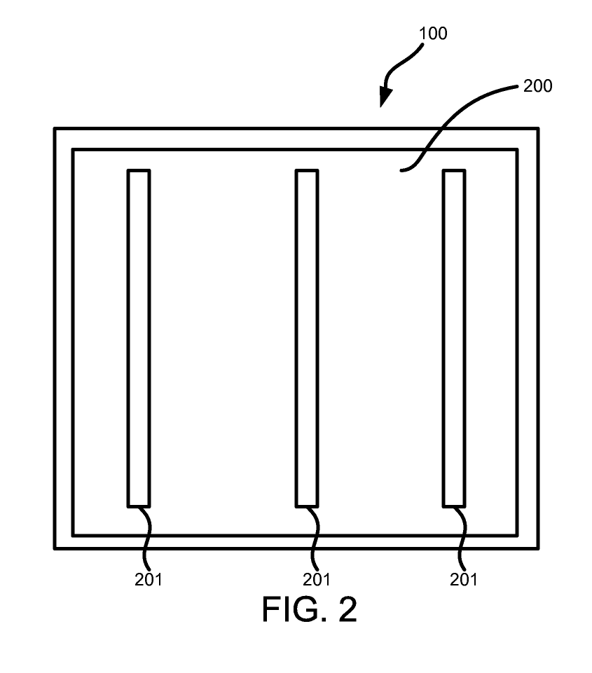

FIG. 2 is a perspective view of an embodiment of counterdoping in a solar cell. In one particular embodiment using counterdoping, contact regions 201 are heavily doped and are not counterdoped. Emitter region 200 not in the area of the contacts is counterdoped to decrease the effective dopant concentration. Emitter region 200 corresponds to emitter 102 in FIG. 1, while contact regions 201 correspond to the emitter 102 located beneath the conductors 104 in FIG. 1. As described above, the lightly doped emitter 200 causes less recombination of carriers, thereby improving efficiency. In addition, heavily doped contact regions 201 improve the conductance of carrier to the conductors.

In the embodiments of the process described herein, the dopants may be Group III or Group V elements, such as, for example, phosphorus, arsenic, boron, antimony, aluminum or indium. Other dopant species also may be used and this application is not limited merely to the dopants listed.

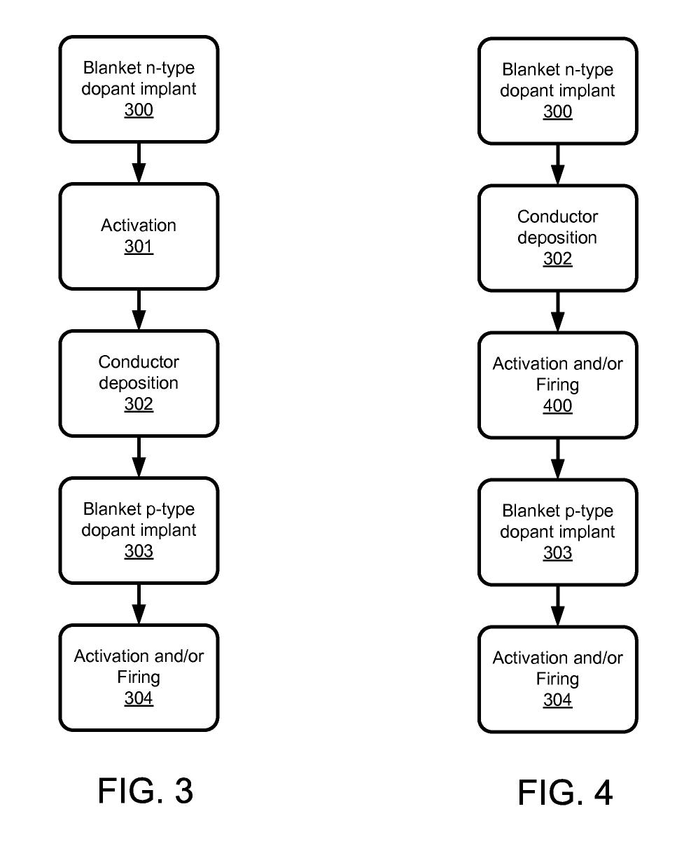

FIG. 3 is a first embodiment of a solar cell fabrication process flow. This process flow will create an “N on P” solar cell without the use of a mask. This decreases complexity of the manufacturing process because mask alignment is not required during implantation.

First, an n-type dopant blanket implant 300 is performed on the solar cell to form the emitter. This n-type dopant may be a Group V element such as phosphorus, for example. Blanket doping may be performed in many ways. For example, blanket doping of a region of the solar cell or the entire solar cell may be performed using ion implantation, such as with a beam-line ion implanter or a plasma doping ion implanter. Blanket doping also may be performed using diffusion in a furnace using either at least one gas or at least one paste on the solar cell substrate. This is followed by an activation step 301, if required, in this particular embodiment.

Next, conductor deposition 302 is performed on the surface of the substrate. In one embodiment, the conductors are the conductors 104 from FIG. 1. In some embodiments, these conductors are between 100 and 500 micrometers (um) in width. In other embodiments, these conductors may be of lesser width. By depositing these conductors, spaces are created therebetween. These spaces are not covered by the conductors, such as the conductors 104 from FIG. 1, and therefore can be implanted by subsequent process steps. This is followed by a p-type dopant blanket implant 303 that is performed on the solar cell. This p-type dopant may be a Group III element, such as boron, for example. The conductors will block part of the p-type dopant from reaching the surface of the solar cell while forming the doped region in the space between the conductors. This will compensate for the high dose of the n-type dopant blanket implant 300 in the areas between the conductors. The depth of this p-type blanket implant 303 varies. For example, the species, energy and dose of the implanted ion affect the depth of the implant. Those skilled in the art can accurately estimate the depth of an implant based on these parameters. Effectively, this p-type blanket implant 303 will decrease the conductivity of the regions implanted during the n-type dopant blanket implant 300 that are not blocked by the conductors. Thus, a high dose of n-type dopant is retained under the conductors, but compensation (counterdoping) leads to a lower conductivity elsewhere a low dose of n-type dopant is created elsewhere in the emitter.

The conductors are then fired. This may be part of the activation and/or firing step 304. This may require a single step or two separate steps. If the firing temperature is too low to fully activate the p-type dopant, a flash anneal or laser anneal, such as an excimer laser anneal (ELA), step may be required subsequently for activation. A flash anneal or laser anneal step may not damage the conductors. The reflectivity of the conductors assists in preventing damage because the conductors will reflect the light generated during the flash or laser anneal step. Thus, the conductors will not be melted. The laser anneal step may activate between the conductors in another embodiment.

FIG. 4 is a second embodiment of a solar cell fabrication process flow. In this embodiment, the blanket n-type dopant implant 300 is followed by the conductor deposition 302. This is then followed by an activation and/or firing step 400. The firing of the conductors, such as metal lines, may serve as a full or partial activation step 400. A blanket p-type dopant implant 303 occurs after the activation and/or firing step 400. Again, the conductors block part of the implanted p-type dopant implant 303. A subsequent activation and/or firing step 304 also may occur.

In one particular embodiment, an anti-reflective coating, such as a SiN layer, is added to the solar cell manufactured using the embodiments illustrated in FIGS. 3-4. This may be added, for example, after the activation 301, after the blanket p-type dopant implant 303, before conductor deposition 302, or after the activation and/or firing 304 or 400. In yet another embodiment, a high-temperature deposition of SiN is performed. This high-temperature deposition may eliminate the need for an activation step. The firing step and high-temperature deposition may be sufficient to activate the dopants.

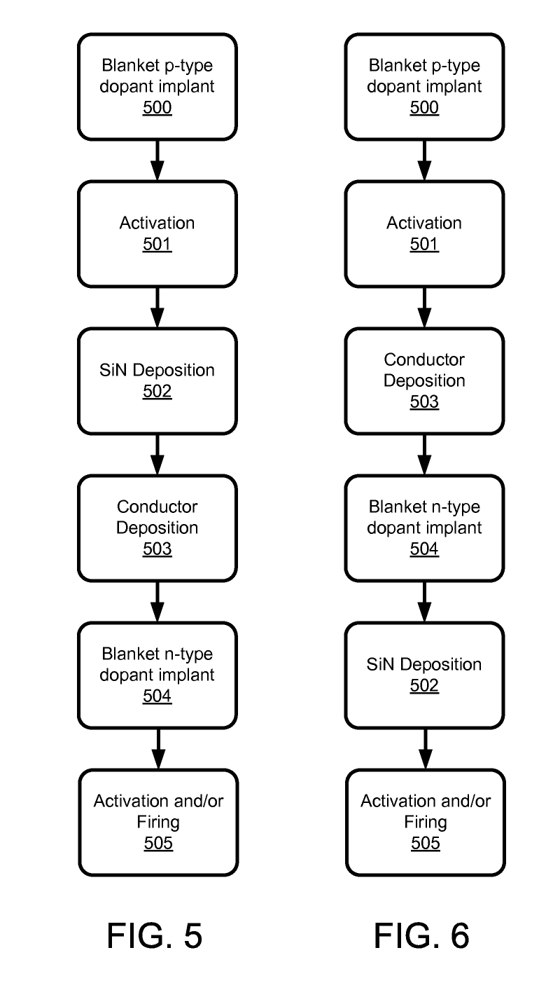

FIGS. 5-8 are embodiments of a solar cell fabrication process flow. These will create a “P on N” solar cell without the use of a mask. In all four instances, a blanket p-type dopant implant 500 is performed to form the emitter. This p-type dopant may be a Group III element such as, for example, boron. This p-type dopant implant 500 is followed by an activation 501, if necessary. In each example, the activation and/or firing 505 may be two separate steps, or the activation and firing may be performed during a single step.

The embodiments of FIGS. 5-8 use a p-type doped emitter, which, in one embodiment is formed with an implant of a Group III element, such as boron. The second implant to form the doped region between the conductors is an n-type dopant such as a Group V element, for example, phosphorus or arsenic. The activation energy of boron is higher than that of phosphorus or arsenic. Therefore, the first activation step, which requires the higher temperature to activate the boron, may be performed prior to the conductor deposition 503. This prevents damage to or melting of the conductors. Furthermore, the lower activation energy of phosphorus or arsenic allows a lower temperature to be used for activation and/or firing 505. This lower temperature may allow the single step activation and firing 505. It also may enable the use of a laser anneal step to activate.

In FIG. 5, the activation 501 is followed by a SiN deposition 502 and conductor deposition 503. The presence of the SiN may passivate the p-type doped emitter. Passivation is the termination of bonds of the solar cell with elements to assure chemical stability of the surface. The presence of the elements means that the bonds of the solar cell are not dangling. Then the blanket n-type dopant implant 504 is performed. The n-type dopant may be, for example, a Group V element, such as phosphorus or arsenic. This blanket n-type dopant implant 504 implants through the SiN layer, which may change its optical properties and may further passivate the solar cell. This is then followed by activation and/or firing 505. Those regions that were exposed to both blanket implants retain the conductivity of the first dopant, however, the amount of conductivity is reduced as compared to those regions beneath the conductors.

In FIG. 6, the activation 501 is followed by a conductor deposition 503 and the blanket n-type dopant implant 504. The n-type dopant may be, for example, a Group V element, such as phosphorus or arsenic. This is followed by the SiN deposition 502 and the activation and/or firing 505.

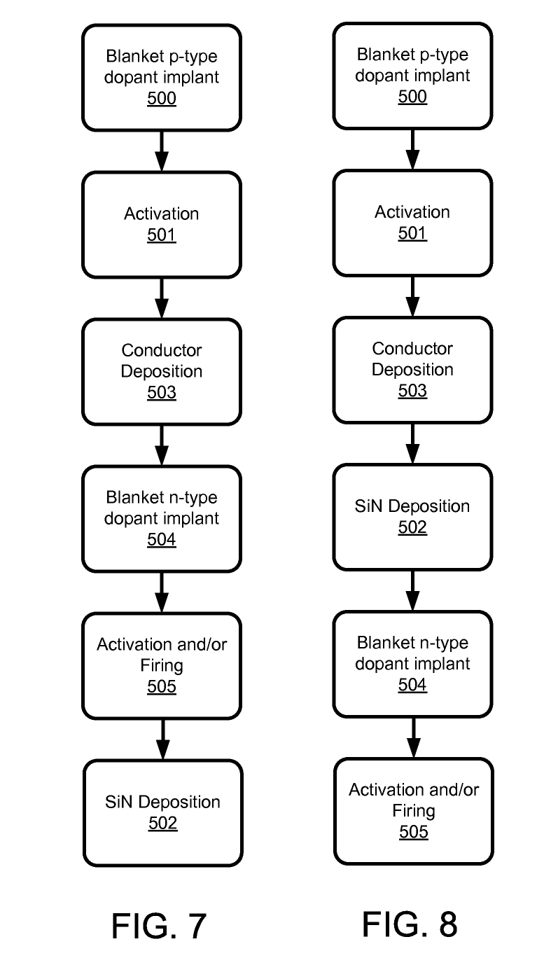

In FIG. 7, the activation 501 is followed by a conductor deposition 503 and the blanket n-type dopant implant 504. The n-type dopant may be, for example, a Group V element, such as phosphorus or arsenic. This is followed by the activation and/or firing 505 and the SiN deposition 502.

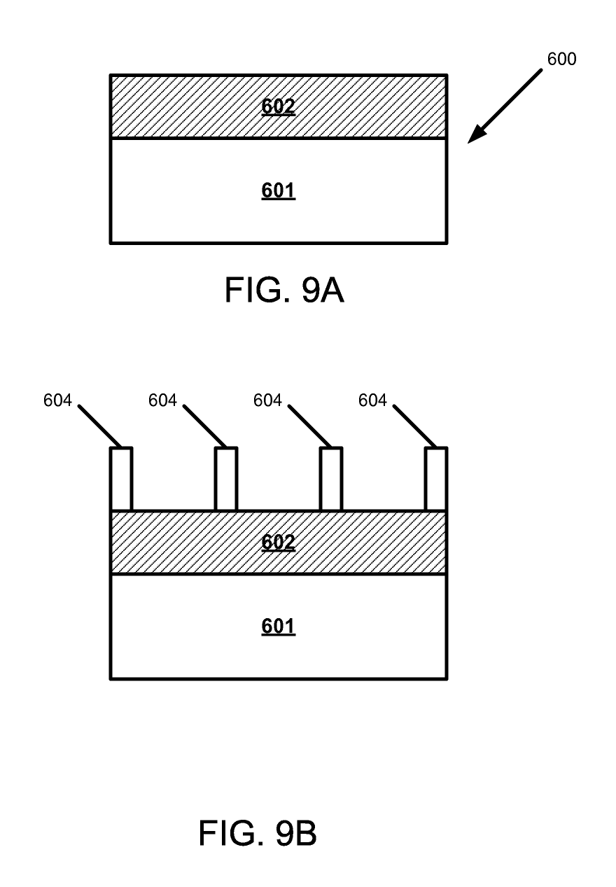

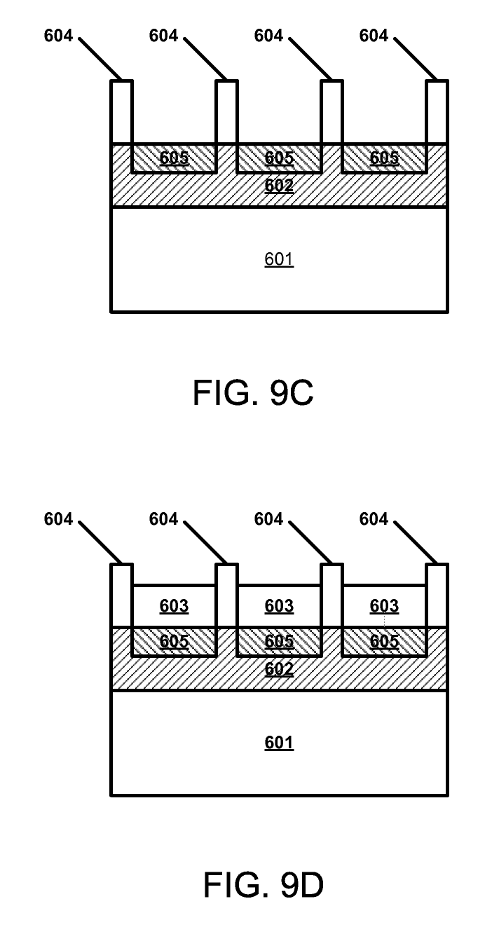

FIG. 9A-9D show the substrate 600 as the steps of FIG. 7 are performed. First, as shown in FIG. 9A, a blanket p-type dopant implant is performed. This blanket implant will result in a p-type emitter region 602, on an n-type base 601. The depth of the implanted region 602 is determined based on the parameters of the blanket implant, the species used for the implant and the anneal parameters, such as time and peak temperature. The p-type dopant then is activated. After the activation 501, the conductors 604 are deposited on the implanted region 602, as shown in FIG. 9B.

After the conductors 604 have been deposited, a second implant is performed. This implant is an n-type dopant, which counteracts the effect of the earlier p-type dopant in the p-type implanted region 602, thereby reducing the effective doping of all regions exposed to the second implant. Note that the second implant must be performed after the conductors are deposited, as the conductors 604 serve as the mask for this second implant, thereby preventing the second implant from affecting the portion of the p-type implanted region 602 directly beneath the conductors 604. FIG. 9C shows the effect of the second implant on the emitter region 602, in that regions of lesser conductivity 605 are created between the conductors 604. These regions of lesser conductivity 605 are still p-type. After the second implant is completed, an activation step is performed. After this is completed, the SiN 603 is deposited, as shown in FIG. 9D.

As noted above, the first implant, conductor deposition and second implant must be performed in that sequence. However, the additional steps of the activation of p-dopant, SiN deposition, and the activation of n-dopant, can be performed at various points during the process, as illustrated by the four embodiments shown in FIGS. 4-7. Furthermore, while a blanket implant may be used to make the p-type emitter region 602, other doping or doping introduction methods also may be used.

Turning back to FIG. 8, the activation 501 is followed by a conductor deposition 503 and the SiN deposition 502. This is followed by the blanket n-type dopant implant 504. The n-type dopant may be, for example, a Group V element, such as phosphorus or arsenic. This is followed by the activation and/or firing 505.

In the embodiments of FIGS. 5-8, the presence of the n-type dopant in the p-type emitter may allow passivation. Counterdoping with phosphorus, for example, can passivate a boron emitter. It also may enable use of SiO₂ for passivation.

In one specific embodiment, one or both implant steps of the embodiments of FIGS. 3-8 are performed on a cooled solar cell. Reducing the temperature of the solar cell may prevent damage to the silicon lattice. Such damage, if not fully repaired upon dopant activation, may cause leakage current within the solar cell.

Activation step 301 and activation step 501 may include an oxidation step in addition to the activation. This may allow an oxide layer to be grown on the solar cell.

The embodiments of the process described herein eliminate the photolithography or mask step. Photolithography is expensive, complex, and requires extra process steps. A stencil or shadow mask may need aligning to ensure proper portions of the solar cell are implanted. Instead, the implants in the embodiments of the process described herein allow the conductors to serve as the mask for the implant rather than photoresist or a stencil or shadow mask. This eliminates alignment and process steps. This also reduces the manufacturing complexity and manufacturing costs for solar cells.

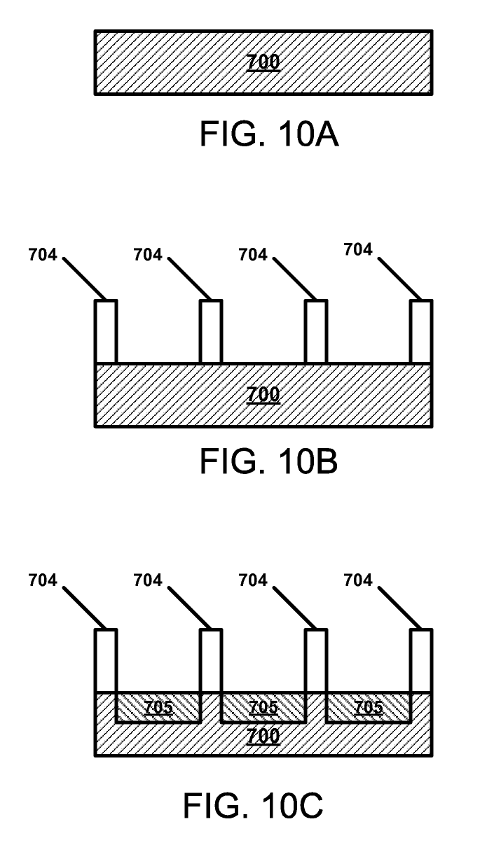

In another embodiment, the initial doping of the substrate is performed prior to the process described herein. For example, a substrate may be doped such as by diffusion. FIG. 10A shows a substrate 700 that has a conductivity. This may be accomplished using a blanket diffusion or other process. This may have the same effect as the blanket doping 300 described in the embodiments shown in FIGS. 3-4 and the blanket doping 500 described in the embodiments shown in FIGS. 5-8. In this embodiment, as seen in FIG. 10B, the conductors 704 are deposited on the substrate 700. After the conductors 704 have been deposited, a blanket doping of a dopant having an opposite conductivity of the substrate 700 is performed. This creates regions 705 between the conductors 704 which are more lightly doped than the other regions of the substrate 700.

The embodiments shown in FIGS. 3-10 show the use of counterdoping to reduce the amount of conductivity of the region not covered by or between the conductors, while retaining the same conductivity under the conductors.

The terms and expressions which have been employed herein are used as terms of description and not of limitation, and there is no intention in the use of such terms and expressions of excluding any equivalents of the features shown and described (or portions thereof). It is also recognized that various modifications are possible within the scope of the claims. Other modifications, variations, and alternatives are also possible. Accordingly, the foregoing description is by way of example only and is not intended as limiting.

What is claimed is:

1. A method of creating regions of different amounts of conductivity on the surface of a solar cell comprising:
performing a first blanket doping using a first dopant on a surface of said solar cell, such that said surface comprises a doped region;
depositing conductors onto said surface of said solar cell after said first blanket doping, each pair of said conductors forming a space between; and
performing a second blanket doping using a second dopant on said surface after said depositing said conductors, wherein said first dopant and said second dopant comprise opposite conductivities and whereby said second dopant is implanted through said space between said conductors and wherein said doped region retains the conductivity of said first dopant.

2. The method of claim 1, wherein said first blanket doping is performed via furnace diffusion.

3. The method of claim 1, wherein said first blanket doping and said second blanket doping are performed via ion implantation.

4. The method of claim 1, wherein said first blanket doping is performed via plasma doping.

5. The method of claim 1, further comprising performing an activation step subsequent said first blanket doping of said first dopant.

6. The method of claim 5, wherein said activation step is performed prior to said depositing of said conductors.

7. The method of claim 5, wherein said activation step is performed subsequent to said depositing of said conductors.

8. The method of claim 1, further comprising depositing an anti-reflective coating onto said surface of said solar cell.

9. The method of claim 8, wherein said anti-reflective coating is deposited prior to depositing said conductors.

10. The method of claim 8, wherein said anti-reflective coating is deposited subsequent to depositing said conductors.

11. The method of claim 10, wherein said anti-reflective coating is deposited subsequent to said second blanket doping.

12. The method of claim 1, wherein said first dopant comprises a Group III element.

13. The method of claim 1, wherein said first dopant comprises a Group V element.

14. A method of doping a substrate, comprising
depositing conductors onto a surface of said substrate; and
performing an ion implantation on said surface using a dopant after depositing said conductors, whereby said conductors prevent said dopant from implanting said substrate beneath said conductors.

15. The method of claim 14, wherein said substrate has an initial conductivity prior to said depositing of said conductors.

16. The method of claim 15, wherein said dopant has a conductivity opposite of said initial conductivity of said substrate.

17. The method of claim 16, wherein said dopant comprises a Group III element.

18. The method of claim 16 wherein said dopant comprises a Group V element.

19. The method of claim 14, wherein said substrate comprises a solar cell.
